(19) United States
(12) Patent Application Publication
(10) Pub. No.: US 2024/0267020 A1
(43) Pub. Date: Aug. 8, 2024

(54) PIEZOELECTRIC RESONATOR PLATE AND PIEZOELECTRIC RESONATOR DEVICE

(71) Applicant: DAISHINKU CORPORATION, Kakogawa-shi, Hyogo (JP)

(72) Inventors: Manabu ONISHI, Kakogawa-shi (JP); Hiroki FUJIWARA, Kakogawa-shi (JP)

(73) Assignee: DAISHINKU CORPORATION, Kakogawa-shi, Hyogo (JP)

(21) Appl. No.: 18/563,142

(22) PCT Filed: Jun. 22, 2022
(86) PCT No.: PCT/JP2022/024902

§ 371 Date: Nov. 21, 2023

(30) Foreign Application Priority Data
Jun. 25, 2021 (JP) 2021-105678

(51) Int. Cl. H03H 9/02; H03H 9/10; H03H 9/19

(52) U.S. Cl. CPC H03H 9/02133; H03H 9/1035; H03H 9/19

(57) ABSTRACT

A crystal resonator plate according to one or more embodiments may include: a vibrating part; an external frame part surrounding an outer periphery of the vibrating part; and a support part connecting the vibrating part to the external frame part. A plurality of crystal faces is formed on respective side surfaces of the external frame part and the support part. The respective side surfaces are connected to a connecting part of the external frame part and the support part. A plurality of ridge lines is formed by the plurality of crystal faces. An intersection blocking part is provided on the connecting part of the external frame part and the support part, on at least one side of a first main surface side and a second main surface side thereof, to block intersection of two or more of the ridge lines on the connecting part.

### TECHNICAL FIELD

The present invention relates to a piezoelectric resonator plate and a piezoelectric resonator device including the piezoelectric resonator plate.

### BACKGROUND ART

Recently, in various electronic devices, the operating frequencies have increased and the package sizes (especially, the heights) have decreased. According to such an increase in operating frequency and a reduction in package size, there is also a need for piezoelectric resonator devices (such as a crystal resonator and a crystal oscillator) to be adaptable to the increase in operating frequency and the reduction in package size.

In this kind of piezoelectric resonator devices, a housing is constituted of a substantially rectangular parallelepiped package. The package is constituted of: a first sealing member and a second sealing member both made of, for example, glass or crystal; and a piezoelectric resonator plate made of, for example, crystal. On respective main surfaces of the piezoelectric resonator plate, excitation electrodes are formed. The first sealing member and the second sealing member are laminated and bonded via the piezoelectric resonator plate. Thus, a vibrating part (with the excitation electrodes) of the piezoelectric resonator plate, which is disposed in the package (in the internal space), is hermetically sealed (see, for example, Patent Document 1). Hereinafter, this type of laminated structure of the piezoelectric resonator device is referred to as a “sandwich structure”.

### PRIOR ART DOCUMENT

### Patent Document

[Patent Document 1] JP 2010-252051 A

### SUMMARY OF THE INVENTION

### Problem to be Solved by the Invention

In the above-described piezoelectric resonator device, the piezoelectric resonator plate has a configuration including a vibrating part, an external frame part surrounding the outer periphery of the vibrating part, and a support part (bridge part) connecting the vibrating part to the external frame part. In other words, the piezoelectric resonator plate is a piezoelectric substrate made of crystal or the like, in which the vibrating part, the support part and the external frame part are integrally formed. However, this type of piezoelectric resonator plate has such a problem that a connecting part of the vibrating part and the support part is likely to be broken. The reason is considered as follows. When processing the piezoelectric resonator plate by wet etching, a plurality of crystal faces is formed on side surfaces of the vibrating part and the support part, which form a plurality of ridge lines. And in such a case, if multiple ridge lines are concentrated on both end parts of a specific ridge line, it may cause break along the specific ridge line. This problem may also occur on a connecting part of the external frame part and the support part of the piezoelectric resonator plate.

The present invention was made in consideration of the above circumstances. An object of the present invention is to provide a piezoelectric resonator plate that can prevent generation of break on the connecting part of the vibrating part and the support part, and on the connecting part of the external frame part and the support part. Also, another object of the present invention is to provide a piezoelectric resonator device including the above piezoelectric resonator plate.

### Means for Solving the Problem

In order to solve the above problem, a piezoelectric resonator plate of the present invention includes: a vibrating part; an external frame part surrounding an outer periphery of the vibrating part; and a support part connecting the vibrating part to the external frame part. A plurality of crystal faces is formed on a side surface of the external frame part and on a side surface of the support part. Both side surfaces are connected to a first connecting part of the external frame part and the support part. A plurality of ridge lines is formed by the plurality of crystal faces. A first intersection blocking part is provided on the first connecting part, on at least one side of a first main surface side and a second main surface side thereof, so as to block intersection of two or more of the plurality of ridge lines on the first connecting part. Note that the above plurality of ridge lines does not include the outer peripheral edge of the first intersection blocking part.

With the above-described configuration, the first intersection blocking part prevents the concentration of the plurality of ridge lines formed by the plurality of crystal faces in one point on the first connecting part of the external frame part and the support part. In this way, it is possible to eliminate concentration of stress in one point on the first connecting part of the external frame part and the support part, and also to prevent generation of cracks that originate from the stress concentration point. Thus, it is possible to prevent the first connecting part of the external frame part and the support part from being broken.

In the above-described configuration, it is preferable that a plurality of crystal faces is formed on a side surface of the vibrating part and on the side surface of the support part. Both side surfaces are connected to a connecting part of the vibrating part and the support part, and a plurality of ridge lines is formed by the plurality of crystal faces. Also, it is preferable that a second intersection blocking part is provided on the connecting part of the vibrating part and the support part, on at least one side of the first main surface side and the second main surface side thereof, so as to block intersection of two or more of the plurality of ridge lines on the connecting part. In this way, by providing the intersection blocking parts respectively on both sides of the support part in the longitudinal direction, it is possible to disperse the stress, which prevents the connecting part from being broken.

In the above-described configuration, it is preferable that the first intersection blocking part is provided on one side of the first main surface side and the second main surface side, and that the second intersection blocking part is provided on the other side of the first main surface side and the second main surface side. In this way, by providing the intersection blocking parts respectively on both the first main surface side and the second main surface side, it is possible to disperse the stress, which prevents the connecting part from being broken.

In the above-described configuration, it is preferable that a third intersection blocking part is provided on a second connecting part of the external frame part and the support part. In this way, by providing the third intersection blocking part in addition to the first and second intersection blocking parts, it is possible to disperse the stress, which prevents the connecting part from being broken.

Also, a piezoelectric resonator plate of the present invention includes: a vibrating part; an external frame part surrounding an outer periphery of the vibrating part; and a support part connecting the vibrating part to the external frame part. A plurality of crystal faces is formed on a side surface of the vibrating part and on a side surface of the support part. Both side surfaces are connected to a connecting part of the vibrating part and the support part. A plurality of ridge lines is formed by the plurality of crystal faces. A second intersection blocking part is provided on the connecting part of the vibrating part and the support part, on at least one side of a first main surface side and a second main surface side thereof, so as to block intersection of two or more of the plurality of ridge lines on the connecting part. Note that the above plurality of ridge lines does not include the outer peripheral edge of the second intersection blocking part.

With the above-described configuration, the second intersection blocking part prevents the concentration of the plurality of ridge lines formed by the plurality of crystal faces in one point on the connecting part of the vibrating part and the support part. In this way, it is possible to eliminate concentration of stress in one point on the connecting part of the vibrating part and the support part, and also to prevent generation of cracks that originate from the stress concentration point. Thus, it is possible to prevent the connecting part of the vibrating part and the support part from being broken.

In the above-described configuration, it is preferable that each intersection blocking part is a new crystal face (for example, a C face and an R face) or a projection part. The intersection blocking part having the above shape can be easily formed by arranging the shape of a photomask when processing the piezoelectric resonator plate by wet etching.

Also in the above-described configuration, it is preferable that the piezoelectric resonator plate is an AT-cut crystal plate, and the first main surface and the second main surface are provided to be parallel to the XZ′ plane of the AT-cut crystal plate. It is also preferable that the first main surface is provided on the side of the +Y direction while the second main surface is provided on the side of the −Y direction. In this case, the piezoelectric resonator plate preferably has only one support part, and this support part extends from a corner part positioned in the +X direction and in the −Z′ direction of the vibrating part toward the −Z′ direction. It is also preferable that the side surface of the support part is a side surface on the side of the −X direction of the support part, and the side surface of the external frame part is connected to the side surface of the support part.

Also, the present invention may be realized as a piezoelectric resonator device including the piezoelectric resonator plate having any one of the above-described configurations. The piezoelectric resonator device also includes a first sealing member that covers a first main surface of the vibrating part of the piezoelectric resonator plate and a second sealing member that covers a second main surface of the vibrating part of the piezoelectric resonator plate. The first sealing member is bonded to the piezoelectric resonator plate, and also the second sealing member is bonded to the piezoelectric resonator plate. Thus, the vibrating part of the piezoelectric resonator plate is sealed. With the piezoelectric resonator device including the piezoelectric resonator plate having the above-described configuration, it is possible to obtain the functions and effects similar to those of the above-described piezoelectric resonator plate. That is, when using the piezoelectric resonator plate with a frame body in which the vibrating part is connected to the external frame part by the support part, it is possible, first of all, to reduce the size and height of the piezoelectric resonator device. In addition, in this piezoelectric resonator device thus made smaller and thinner, it is possible to prevent generation of break on the connecting part of the vibrating part and the support part, or on the connecting part of the external frame part and the support part.

### Effects of the Invention

With the present invention, it is possible to provide a piezoelectric resonator plate capable of preventing break of a connecting part of a vibrating part and a support part or break of a connecting part of an external frame part and the support part. Also, it is possible to provide a piezoelectric resonator device including the piezoelectric resonator plate.

### BRIEF DESCRIPTION OF THE DRAWINGS

FIG. 1 is a schematic configuration diagram schematically illustrating a configuration of a crystal resonator according to an embodiment.

FIG. 2 is a schematic plan view illustrating a first main surface of a first sealing member of the crystal resonator.

FIG. 3 is a schematic plan view illustrating a second main surface of the first sealing member of the crystal resonator.

FIG. 4 is a schematic plan view illustrating a first main surface of a crystal resonator plate according to the embodiment.

FIG. 5 is a schematic plan view illustrating a second main surface of the crystal resonator plate according to the embodiment.

FIG. 6 is a schematic plan view illustrating a first main surface of a second sealing member of the crystal resonator.

FIG. 7 is a schematic plan view illustrating a second main surface of the second sealing member of the crystal resonator.

FIG. 8 is a schematic perspective view illustrating an example of a connecting part of a vibrating part and a support part on the first main surface side.

FIG. 9 is a schematic perspective view illustrating an example of the connecting part of the vibrating part and the support part on the second main surface side.

FIG. 10 is a schematic perspective view illustrating an example of the connecting part of the vibrating part and the support part on the second main surface side.

FIG. 11 is a schematic bottom view explaining an inclination angle and a slope length of an intersection blocking part.

FIG. 12 are schematic bottom views each illustrating an example of the crystal resonator plate having a plurality of intersection blocking parts.

### MODE FOR CARRYING OUT THE INVENTION

Hereinafter, an embodiment of the present invention will be described in detail with reference to the drawings. In the embodiment below, a piezoelectric resonator device to which the present invention is applied is exemplarily shown as a crystal resonator.

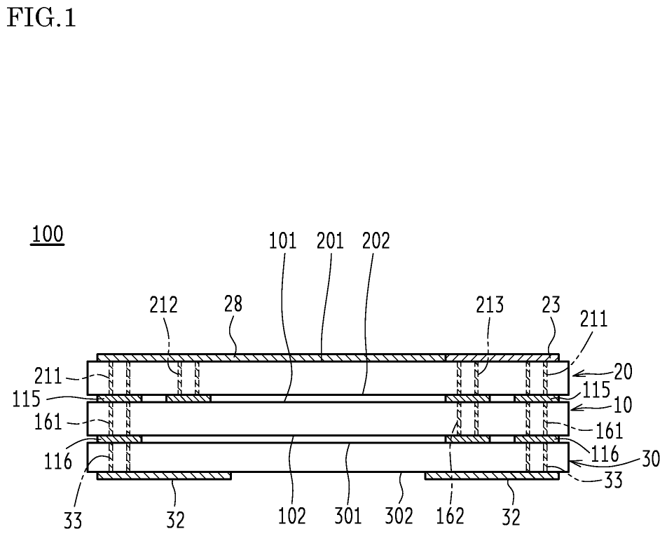

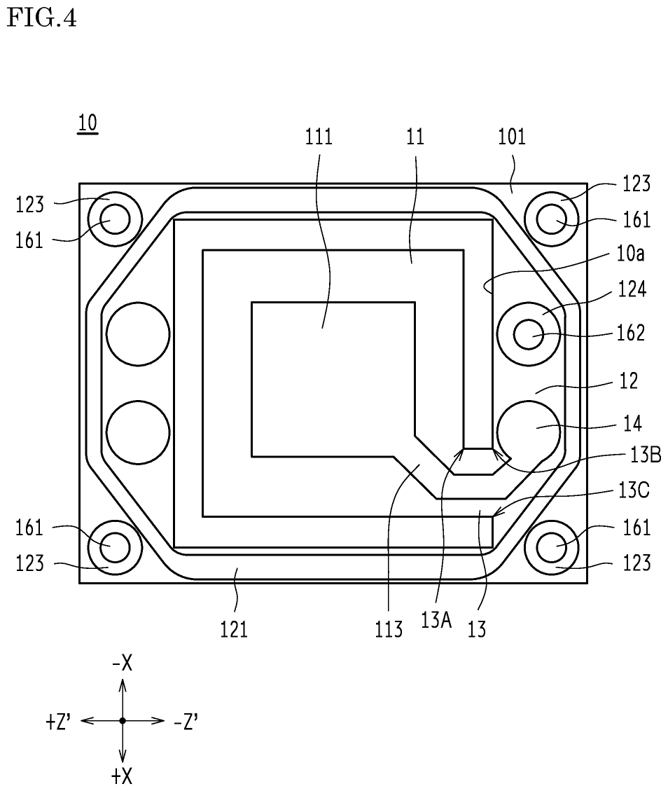

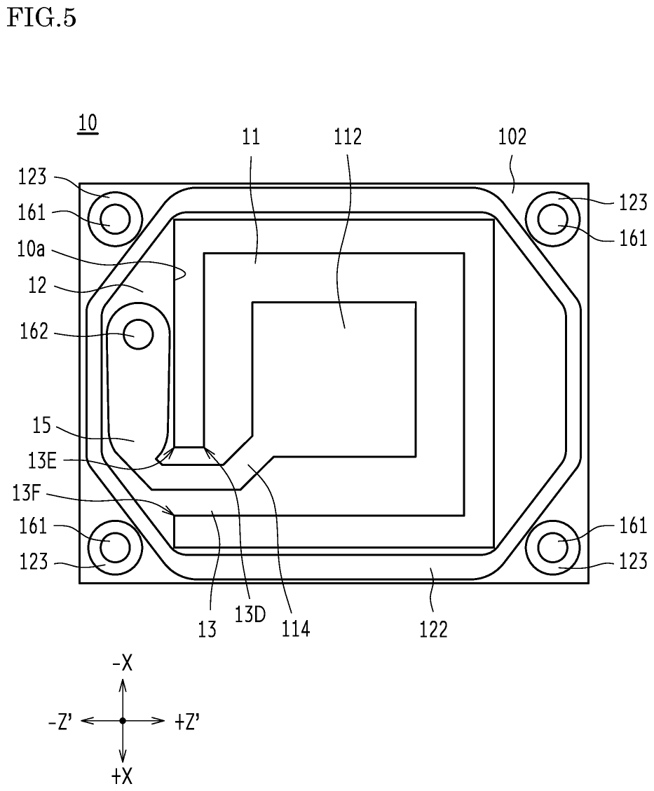

First, a basic configuration of a crystal resonator 100 according to this embodiment is described. As shown in FIG. 1, the crystal resonator 100 includes: a crystal resonator plate (piezoelectric resonator plate) 10; a first sealing member 20; and a second sealing member 30. In this crystal resonator 100, the crystal resonator plate 10 is bonded to the first sealing member 20, and furthermore the crystal resonator plate 10 is bonded to the second sealing member 30. Thus, a package having a sandwich structure is formed so as to have a substantially rectangular parallelepiped shape. That is, in the crystal resonator 100, the first sealing member 20 and the second sealing member 30 are bonded to respective main surfaces of the crystal resonator plate 10, thus an internal space (cavity) of the package is formed. In this internal space, a vibrating part 11 (see FIGS. 4 and 5) is hermetically sealed.

The crystal resonator 100 according to this embodiment has, for example, a package size of 1.0×0.8 mm, which is reduced in size and height. According to the size reduction, no castellation is formed in the package. Through holes are used for conduction between electrodes, as described later. The crystal resonator 100 is electrically connected to an external circuit board (not shown) provided outside via solder.

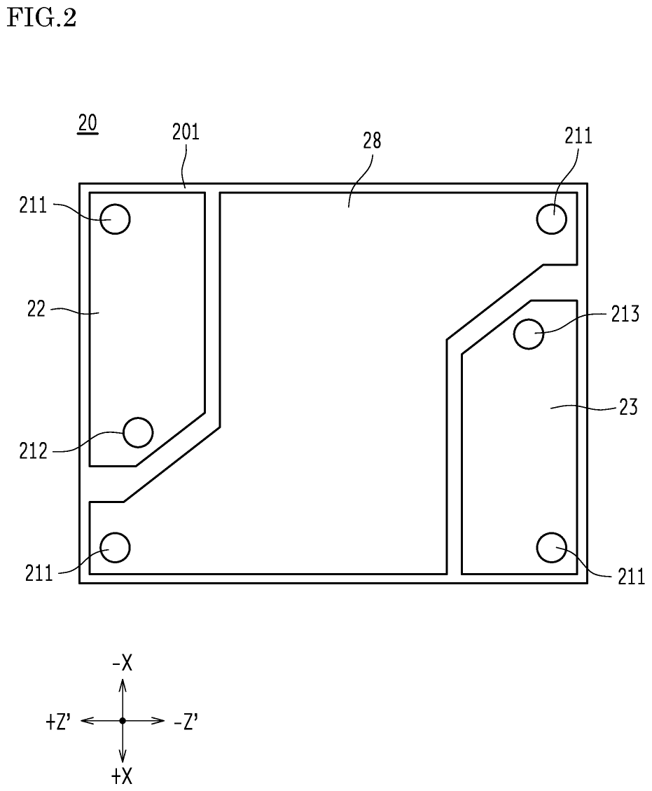

Next, the respective components of the above-described crystal resonator 100 (i.e. the crystal resonator plate 10, the first sealing member 20 and the second sealing member 30) are described with reference to FIGS. 1 to 7. Here, each of the components is described as a single body without being bonded. FIGS. 2 to 7 merely show respective configuration examples of the crystal resonator plate 10, the first sealing member 20 and the second sealing member 30, and thus the present invention is not limited thereto.

The crystal resonator plate 10 according to this embodiment is a piezoelectric substrate made of crystal as shown in FIGS. 4 and 5. Each main surface (i.e. a first main surface 101 and a second main surface 102) is formed as a smooth flat surface (mirror-finished). In this embodiment, an AT-cut crystal plate that causes thickness shear vibration is used as the crystal resonator plate 10. In the crystal resonator plate 10 shown in FIGS. 4 and 5, each of the main surfaces 101 and 102 of the crystal resonator plate 10 is an XZ′ plane. On this XZ′ plane, the direction parallel to the lateral direction (short side direction) of the crystal resonator plate 10 is the X axis direction, and the direction parallel to the longitudinal direction (long side direction) of the crystal resonator plate 10 is the Z′ axis direction. The AT-cut method is a processing method in which a crystal plate is cut out of synthetic quartz crystal at an angle tilted by 35° 15′ about the X axis from the Z axis, out of the three crystal axes (i.e. an electrical axis (X axis), a mechanical axis (Y axis) and an optical axis (Z axis)) of the synthetic quartz crystal. The X axis of the AT-cut crystal plate equals the crystal axis of the crystal. The Y′ axis and the Z′ axis equal the respective axes that tilt by approximately 35° 15′ from the Y axis and the Z axis out of the crystal axes of the crystal (this cutting angle may be changed to a certain extent within the range in which the frequency temperature characteristics of the AT-cut crystal resonator plate can be adjusted). The Y′ axis direction and the Z′ axis direction correspond to the directions in which the AT-cut crystal is cut out.

A pair of excitation electrodes (i.e. a first excitation electrode 111 and a second excitation electrode 112) is formed, respectively, on the main surfaces 101 and 102 of the crystal resonator plate 10. The crystal resonator plate 10 includes: the vibrating part 11 formed so as to have a substantially rectangular shape; an external frame part 12 surrounding the outer periphery of the vibrating part 11; and a support part (bridge part) 13 that supports the vibrating part 11 by connecting the vibrating part 11 to the external frame part 12. That is, the crystal resonator plate 10 has a configuration in which the vibrating part 11, the external frame part 12 and the support part 13 are integrally formed. The support part 13 extends (protrudes) from only one corner part positioned in the +X direction and in the −Z′ direction of the vibrating part 11 to the external frame part 12 in the −Z′ direction. A penetrating part (slit) 10a is formed between the vibrating part 11 and the external frame part 12 so as to penetrate the crystal resonator plate 10 in the thickness direction. In this embodiment, the crystal resonator plate 10 has only one support part 13 to connect the vibrating part 11 to the external frame part 12. The penetrating part 10a is continuously formed so as to surround the outer periphery of the vibrating part 11. The support part 13 will be described later in detail.

The first excitation electrode 111 is provided on the first main surface 101 side of the vibrating part 11 while the second excitation electrode 112 is provided on the second main surface 102 side of the vibrating part 11. The first excitation electrode 111 and the second excitation electrode 112 are respectively connected to input and output lead-out wirings (i.e. a first lead-out wiring 113 and a second lead-out wiring 114) so that these excitation electrodes are connected to external electrode terminals. The first input lead-out wiring 113 is drawn from the first excitation electrode 111 and connected to a connection bonding pattern 14 formed on the external frame part 12 via the support part 13. The second output lead-out wiring 114 is drawn from the second excitation electrode 112 and connected to a connection bonding pattern 15 formed on the external frame part 12 via the support part 13.

Resonator-plate-side sealing parts to bond the crystal resonator plate 10 respectively to the first sealing member 20 and the second sealing member 30 are provided on the respective main surfaces (i.e. the first main surface 101 and the second main surface 102) of the crystal resonator plate 10. As the resonator-plate-side sealing part on the first main surface 101, a resonator-plate-side first bonding pattern 121 is formed. As the resonator-plate-side sealing part on the second main surface 102, a resonator-plate-side second bonding pattern 122 is formed. The resonator-plate-side first bonding pattern 121 and the resonator-plate-side second bonding pattern 122 are each formed on the external frame part 12 so as to have an annular shape in plan view.

Also, as shown in FIGS. 4 and 5, five through holes are formed in the crystal resonator plate 10 so as to penetrate between the first main surface 101 and the second main surface 102. More specifically, four first through holes 161 are respectively disposed in the four corners (corner parts) of the external frame part 12. A second through hole 162 is disposed in the external frame part 12, on one side in the Z′ axis direction relative to the vibrating part 11 (in FIGS. 4 and 5, on the side of the −Z′ direction). Connection bonding patterns 123 are formed on the respective peripheries of the first through holes 161. Also, on the periphery of the second through hole 162, a connection bonding pattern 124 is formed on the first main surface 101 side while the connection bonding pattern 15 is formed on the second main surface 102 side.

In the first through holes 161 and the second through hole 162, through electrodes are respectively formed along a corresponding inner wall surface of the above through holes so as to establish conduction between the electrodes formed on the first main surface 101 and the second main surface 102. Respective center parts of the first through holes 161 and the second through hole 162 are hollow penetrating parts penetrating between the first main surface 101 and the second main surface 102. The outer peripheral edge of the resonator-plate-side first bonding pattern 121 is disposed so as to be adjacent to the outer peripheral edge of the first main surface 101 of the crystal resonator plate 10 (external frame part 12). The outer peripheral edge of the resonator-plate-side second bonding pattern 122 is disposed so as to be adjacent to the outer peripheral edge of the second main surface 102 of the crystal resonator plate 10 (external frame part 12). In this embodiment, the configuration is exemplarily described, in which five through holes are formed so as to penetrate between the first main surface 101 and the second main surface 102. However, the through holes are not necessarily required to be formed. In place of the through holes, a castellation may be used by cutting out a part of the side surface of the crystal resonator plate 10, and attaching an electrode to an inner wall surface of the cut-out region. (In this case, this configuration is also applied to the first sealing member 20 and the second sealing member 30).

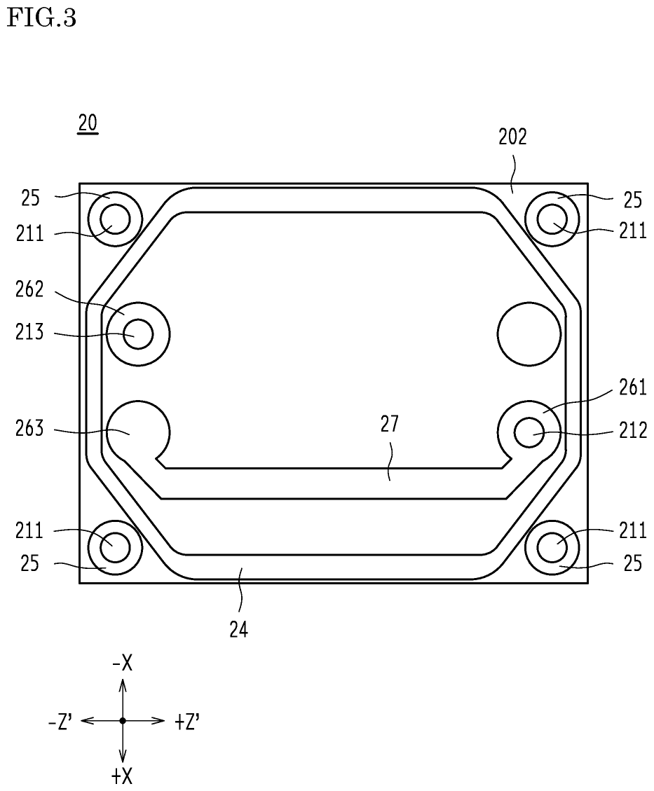

As shown in FIGS. 2 and 3, the first sealing member 20 is a substrate having a rectangular parallelepiped shape that is made of a single AT-cut crystal plate. A second main surface 202 (a surface to be bonded to the crystal resonator plate 10) of the first sealing member 20 is formed as a smooth flat surface (mirror finished). By making the first sealing member 20, which does not have the vibrating part, of the AT-cut crystal plate as in the case of the crystal resonator plate 10, it is possible for the first sealing member 20 to have the same coefficient of thermal expansion as the crystal resonator plate 10. Thus, it is possible to prevent thermal deformation of the crystal resonator 100. Furthermore, the respective directions of the X axis, Y axis and Z′ axis of the first sealing member 20 are the same as those of the crystal resonator plate 10.

As shown in FIG. 2, a first and second terminals 22 and 23 for wiring and a metal film 28 for sealing (for earth connection) are formed on a first main surface 201 (the outer main surface not facing the crystal resonator plate 10) of the first sealing member 20. The first and second terminals 22 and 23 for wiring are provided as the wirings for electrically connecting respectively the first and second excitation electrodes 111 and 112 of the crystal resonator plate 10 to external electrode terminals 32 of the second sealing member 30. The first and second terminals 22 and 23 are respectively provided on both end parts in the Z′ direction. Specifically, the first terminal 22 is provided on the end part in the +Z′ direction while the second terminal 23 is provided on the end part in the −Z′ direction. The first and second terminals 22 and 23 are both formed so as to extend in the X axis direction. The first and second terminals 22 and 23 are each formed so as to have a substantially rectangular shape.

The metal film 28 is disposed between the first terminal 22 and the second terminal 23 at a predetermined distance from both the first terminal 22 and the second terminal 23. The metal film 28 is provided over almost the entire area of the first main surface 201 of the first sealing member 20, except for the area where the first terminal 22 and the second terminal 23 are provided. The metal film 28 is provided so as to cover from the end of the first main surface 201 of the first sealing member 20 in the +X direction to the end thereof in the −X direction.

As shown in FIGS. 2 and 3, six through holes are formed in the first sealing member 20 so as to penetrate between the first main surface 201 and the second main surface 202. More specifically, four third through holes 211 are respectively disposed in the four corners (corner parts) of the first sealing member 20. Fourth and fifth through holes 212 and 213 are disposed respectively in the +Z′ direction and in the −Z′ direction in FIGS. 2 and 3.

In the third through holes 211 and the fourth and fifth through holes 212 and 213, through electrodes are respectively formed along a corresponding inner wall surface of the above through holes so as to establish conduction between the electrodes formed on the first main surface 201 and the second main surface 202. Respective center parts of the third through holes 211 and the fourth and fifth through holes 212 and 213 are hollow penetrating parts penetrating between the first main surface 201 and the second main surface 202. The respective through electrodes of the two third through holes 211 and 211 that are diagonally positioned on the first main surface 201 of the first sealing member 20 (i.e. in FIGS. 2 and 3, the third through hole 211 positioned in the corner part in the +X direction and in the +Z′ direction and the third through hole 211 positioned in the corner part in the −X direction and in the −Z′ direction) are electrically connected via the third metal film 28. Also, the through electrode of the third through hole 211 positioned in the corner part in the −X direction and in the +Z′ direction is electrically connected to the through electrode of the fourth through hole 212 via the first terminal 22. Furthermore, the through electrode of the third through hole 211 positioned in the corner part in the +X direction and in the −Z′ direction is electrically connected to the through electrode of the fifth through hole 213 via the second terminal 23.

On the second main surface 202 of the first sealing member 20, a sealing-member-side first bonding pattern 24 is formed as a sealing-member-side first sealing part so as to be bonded to the crystal resonator plate 10. The sealing-member-side first bonding pattern 24 is formed so as to have an annular shape in plan view. On the second main surface 202 of the first sealing member 20, connection bonding patterns 25 are respectively formed on the peripheries of the third through holes 211. A connection bonding pattern 261 is formed on the periphery of the fourth through hole 212, and a connection bonding pattern 262 is formed on the periphery of the fifth through hole 213. Furthermore, a connection bonding pattern 263 is formed on the side opposite to the connection bonding pattern 261 in the long axis direction of the first sealing member 20 (i.e. on the side of the −Z′ direction). The connection bonding pattern 261 and the connection bonding pattern 263 are connected to each other via a wiring pattern 27. The outer peripheral edge of the sealing-member-side first bonding pattern 24 is disposed so as to be adjacent to the outer peripheral edge of the second main surface 202 of the first sealing member 20.

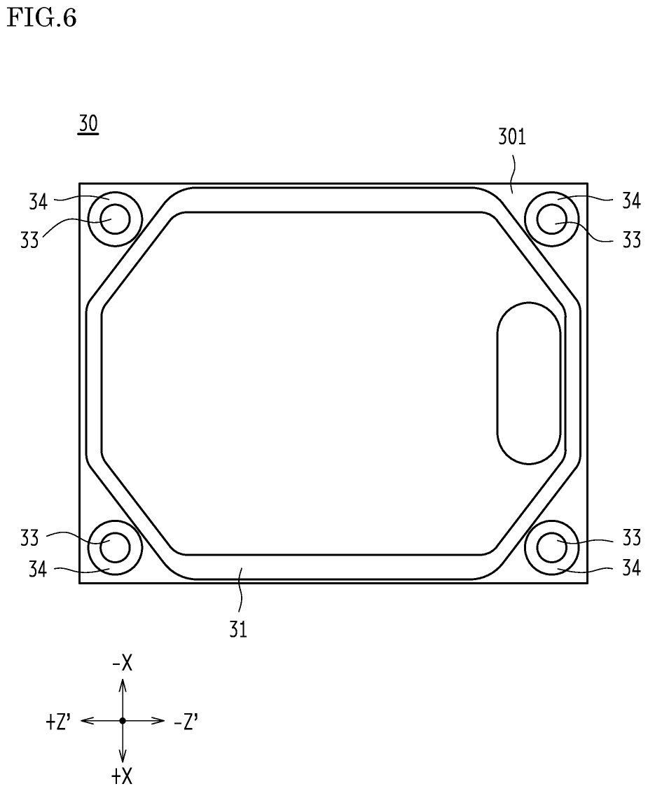

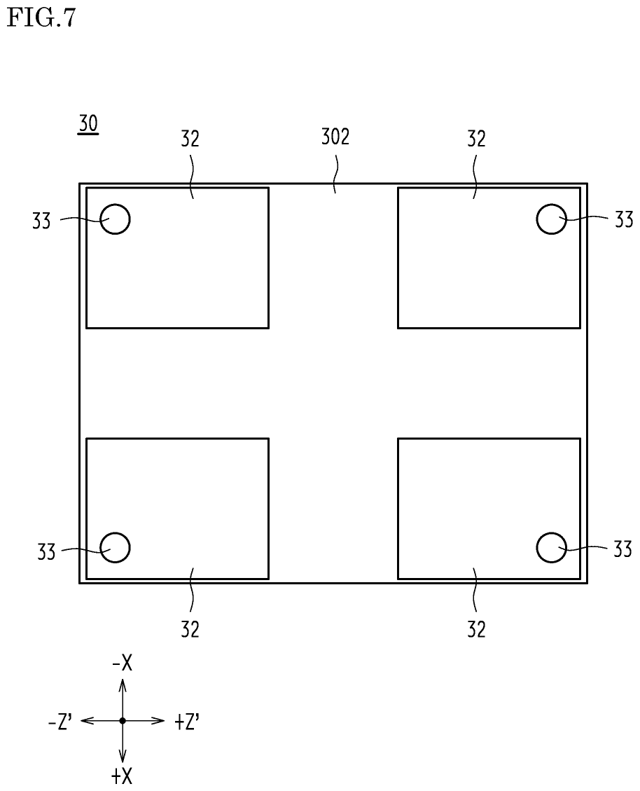

As shown in FIGS. 6 and 7, the second sealing member 30 is a substrate having a rectangular parallelepiped shape that is made of a single AT-cut crystal plate. A first main surface 301 (a surface to be bonded to the crystal resonator plate 10) of the second sealing member 30 is formed as a smooth flat surface (mirror finished). The second sealing member 30 is also preferably made of an AT-cut crystal plate as in the case of the crystal resonator plate 10, and the respective directions of the X axis, Y axis and Z′ axis of the second sealing member 30 are preferably the same as those of the crystal resonator plate 10.

On the first main surface 301 of the second sealing member 30, a sealing-member-side second bonding pattern 31 is formed as a sealing-member-side second sealing part so as to be bonded to the crystal resonator plate 10. The sealing-member-side second bonding pattern 31 is formed so as to have an annular shape in plan view. The outer peripheral edge of the sealing-member-side second bonding pattern 31 is disposed so as to be adjacent to the outer peripheral edge of the first main surface 301 of the second sealing member 30.

On a second main surface 302 (the outer main surface not facing the crystal resonator plate 10) of the second sealing member 30, four external electrode terminals 32 are formed, which are electrically connected to an external circuit board provided outside the crystal resonator 100. The external electrode terminals 32 are respectively located on four corners (corner parts) on the second main surface 302 of the second sealing member 30.

As shown in FIGS. 6 and 7, four through holes are formed in the second sealing member 30 so as to penetrate between the first main surface 301 and the second main surface 302. More specifically, four sixth through holes 33 are respectively disposed in the four corners (corner parts) of the second sealing member 30. In the sixth through holes 33, through electrodes are respectively formed along a corresponding inner wall surface of the sixth through holes 33 so as to establish conduction between the electrodes formed on the first main surface 301 and the second main surface 302. In this way, the respective electrodes formed on the first main surface 301 are electrically conducted to the external electrode terminals 32 formed on the second main surface 302 via the through electrodes formed along the inner wall surfaces of the sixth through holes 33. Also, respective central parts of the sixth through holes 33 are hollow penetrating parts penetrating between the first main surface 301 and the second main surface 302. On the first main surface 301 of the second sealing member 30, connection bonding patterns 34 are respectively formed on the peripheries of the sixth through holes 33.

In the crystal resonator 100 including the crystal resonator plate 10, the first sealing member 20 and the second sealing member 30 as described above, the crystal resonator plate 10 and the first sealing member 20 are subjected to the diffusion bonding in a state in which the resonator-plate-side first bonding pattern 121 and the sealing-member-side first bonding pattern 24 are superimposed on each other, and the crystal resonator plate 10 and the second sealing member 30 are subjected to the diffusion bonding in a state in which the resonator-plate-side second bonding pattern 122 and the sealing-member-side second bonding pattern 31 are superimposed on each other, thus, the package having the sandwich structure as shown in FIG. 1 is produced. Accordingly, the internal space of the package, i.e. the space to house the vibrating part 11 is hermetically sealed.

In this case, the respective connection bonding patterns as described above are also subjected to the diffusion bonding in a state in which they are each superimposed on the corresponding connection bonding pattern. Such bonding between the connection bonding patterns allows electrical conduction of the first excitation electrode 111, the second excitation electrode 112 and the external electrode terminals 32 of the crystal resonator 100. More specifically, the first excitation electrode 111 is connected to the external electrode terminal 32 via the first lead-out wiring 113, the wiring pattern 27, the fourth through hole 212, the first terminal 22, the third through hole 211, the first through hole 161 and the sixth through hole 33 in this order. The second excitation electrode 112 is connected to the external electrode terminal 32 via the second lead-out wiring 114, the second through hole 162, the fifth through hole 213, the second terminal 23, the third through hole 211, the first through hole 161 and the sixth through hole 33 in this order. Also, the metal film 28 is earth-connected (i.e. ground connection, using parts of the external electrode terminals 32) via the third through holes 211, the first through holes 161 and the sixth through holes 33 in this order.

In the crystal resonator 100, the bonding patterns are each preferably made of a plurality of layers laminated on the crystal plate, specifically, a Ti (titanium) layer and an Au (gold) layer deposited, by vapor deposition or sputtering, in this order from the lowermost layer side. Also, the other wirings and electrodes formed on the crystal resonator 100 each preferably have the same configuration as the bonding patterns, which leads to patterning of the bonding patterns, wirings and the electrodes at the same time.

In the above-described crystal resonator 100, sealing parts (seal paths) 115 and 116 that hermetically seal the vibrating part 11 of the crystal resonator plate 10 are formed so as to have an annular shape in plan view. The seal path 115 is formed by the diffusion bonding (Au—Au bonding) of the resonator-plate-side first bonding pattern 121 and the sealing-member-side first bonding pattern 24 as described above. The outer edge and the inner edge of the seal path 115 both have a substantially octagonal shape. In the same way, the seal path 116 is formed by the diffusion bonding (Au—Au bonding) of the resonator-plate-side second bonding pattern 122 and the sealing-member-side second bonding pattern 31 as described above. The outer edge and the inner edge of the seal path 116 both have a substantially octagonal shape.

In the crystal resonator 100 having the seal paths 115 and 116 formed by the diffusion bonding as described above, the first sealing member 20 and the crystal resonator plate 10 have a gap of not more than 1.00 μm. The second sealing member 30 and the crystal resonator plate 10 have a gap of not more than 1.00 μm. That is, the thickness of the seal path 115 between the first sealing member and the crystal resonator plate 10 is not more than 1.00 μm, and the thickness of the seal path 116 between the second sealing member 30 and the crystal resonator plate 10 is not more than 1.00 μm (specifically, the thickness in the Au—Au bonding in this embodiment is 0.15 to 1.00 μm). As a comparative example, the conventional metal paste sealing material containing Sn has a thickness of 5 to 20 μm.

Next, the crystal resonator plate 10 according to this embodiment is described referring to FIGS. 4, 5, 8 and 9.

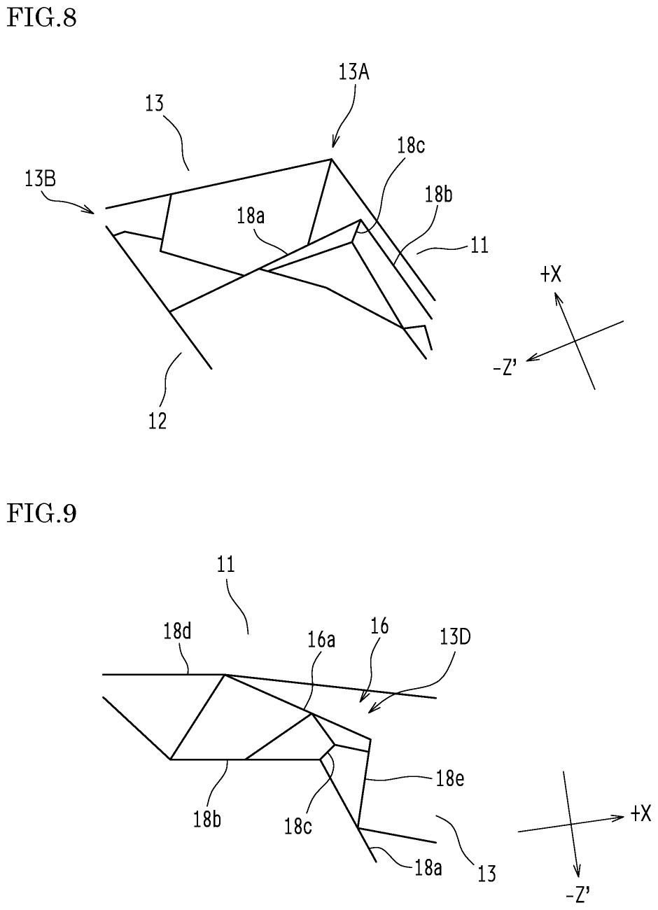

As shown in FIGS. 4 and 5, the crystal resonator plate 10 includes: the vibrating part 11 having a substantially rectangular shape; the external frame part 12 surrounding the outer periphery of the vibrating part 11; and the support part 13 connecting the vibrating part 11 to the external frame part 12. The vibrating part 11, the external frame part 12 and the support part 13 have, on each side surface thereof, a plurality of crystal faces formed by wet etching, as shown in FIGS. 8 and 9.

As shown in FIGS. 8 and 9, a pair of facing main surfaces (i.e. the first and second main surfaces) of the support part 13 is formed to be parallel to the XZ′ plane of the AT-cut crystal. The first main surface is a surface provided on the side of the +Y direction, and the second main surface is a surface provided on the side of the −Y direction. The first main surface of the support part 13 is the same plane as the first main surface of the vibrating part 11. The second main surface of the support part 13 is the same plane as the second main surface of the vibrating part 11. The width direction of the support part 13 is parallel to the X axis direction. Note that in FIGS. 8 and 9, the first and second lead-out wirings 113 and 114 are omitted, which are respectively formed on the first and second main surfaces of the support part 13.

The support part 13 extends toward the −Z′ direction from the side surface of the vibrating part 11 in the −Z′ direction. The side surface of the support part 13 in the −X direction substantially perpendicularly intersects the side surface of the vibrating part 11 in the Z′ direction. The side surface of the support part 13 in the +X direction as well as the side surface of the vibrating part 11 in the +X direction substantially linearly extend. A plurality of crystal faces is formed by wet etching on the side surface of the vibrating part 11 in the −Z′ direction and on the side surface of the support part 13 in the −X direction. These crystal faces form a plurality of ridge lines.

On a connecting part (border part) 13D of the vibrating part 11 and the support part 13 on the second main surface side (i.e. on the side of the −Y direction), an intersection blocking part is provided so as to block the intersection of two or more ridge lines on the connecting part 13D. In this embodiment, a C face (chamfered face) 16 shown in FIG. 9 is provided as the intersection blocking part.

As specifically shown in FIGS. 8 and 9, a plurality of ridge lines 18a-18e is formed on the side surface of the vibrating part 11 in the −Z′ direction and on the side surface of the support part 13 in the −X direction. The C face 16 prevents the three ridge lines 18c, 18d and 18e from intersecting each other on the connecting part 13D of the vibrating part 11 and the support part 13 on the second main surface side. The ridge lines 18c, 18d and 18e are connected to (intersect) an outer peripheral edge 16a of the C face 16. Thus, the C face 16 prevents the ridge lines 18c, 18d and 18e from being concentrated in one point.

The C face 16 as described above can be easily realized by arranging the shape of a photomask when processing the crystal resonator plate 10 by wet etching. Specifically, when performing wet etching to form the penetrating part 10a in the crystal resonator plate 10, it is sufficient to provide a projection part having a shape corresponding to the C face 16 on a photomask, at a part corresponding to the connecting part (border part) 13D of the vibrating part 11 and the support part 13 on the second main surface side.

In this embodiment as described above, the C face 16 prevents the plurality of ridge lines 18c, 18d and 18e formed on the side surface of the vibrating part 11 in the −Z′ direction and on the side surface of the support part 13 in the −X direction from being concentrated in one point on the connecting part 13D of the vibrating part 11 and the support part 13 on the second main surface side. In this way, it is possible to eliminate concentration of stress in one point on the connecting part 13D of the vibrating part 11 and the support part 13 on the second main surface side, and also to prevent generation of cracks that originate from the stress concentration point. Thus, it is possible to prevent the connecting part of the vibrating part 11 and the support part 13 from being broken.

Here, on a connecting part 13A of the vibrating part 11 and the support part 13 on the first main surface side, since the three ridge lines 18a, 18b and 18c are concentrated in one point, and thus stress may concentrate in this point. When the C face 16 is not provided, the ridge lines 18c, 18d and 18e are concentrated in one point, which may also lead to stress concentration in this point. Thus, if the C face 16 is not provided, both end parts of the ridge line 18c may be the stress concentration points, which may cause break along the ridge line 18c.

However in this embodiment, the C face 16 is provided on the connecting part 13D of the vibrating part 11 and the support part 13 on the second main surface side so as to prevent the concentration of the plurality of ridge lines 18c, 18d and 18e in one point, which leads to prevention of break along the ridge line 18c. Therefore, in this embodiment, it is possible to prevent generation of break on the connecting part of the vibrating part 11 and the support part 13 of the crystal resonator plate 10.

In this embodiment, the crystal resonator plate 10 includes: the vibrating part 11; the external frame part 12 surrounding the outer periphery of the vibrating part 11; and a support part (connecting part) 13 that connects the vibrating part 11 to the external frame part 12. The penetrating part 10a is formed between the vibrating part 11 and the external frame part 12 so as to penetrate the crystal resonator plate 10 in the thickness direction. When using such a crystal resonator plate 10 with a frame body in which the vibrating part 11 is connected to the external frame part 12 by the support part 13, it is possible to reduce the size and height of the crystal resonator 100. Also, in this crystal resonator 100 thus made smaller and thinner, it is possible to prevent the connecting part of the vibrating part 11 and the support part 13 of the crystal resonator plate 10 from being broken.

The foregoing embodiment is to be considered in all respects as illustrative and not limiting. The technical scope of the invention is indicated by the appended claims rather than by the foregoing description, and all modifications and changes that come within the meaning and range of equivalency of the claims are intended to be embraced therein.

In the above-described embodiment, the C face 16 as the intersection blocking part is provided on the connecting part 13D of the vibrating part 11 and the support part 13 on the second main surface side. However, such a C face may be provided on the connecting part 13A of the vibrating part 11 and the support part 13 on the first main surface side. Alternatively, the C face may be provided on both the connection part 13A on the first main surface side and the connecting part 13D on the second main surface side, of the vibrating part 11 and the support part 13. When the crystal resonator plate 10 adaptable to high frequency at, for example, 60 MHz or more is used, the thickness of the support part 13 becomes thinner and thus sometimes any C face cannot remain after wet etching. In this case, by performing photomasking with a shape corresponding to the C face on both sides of the first main surface and the second main surface, it is possible to more stably form the C face on at least one surface side of the first main surface side and the second main surface side after wet etching.

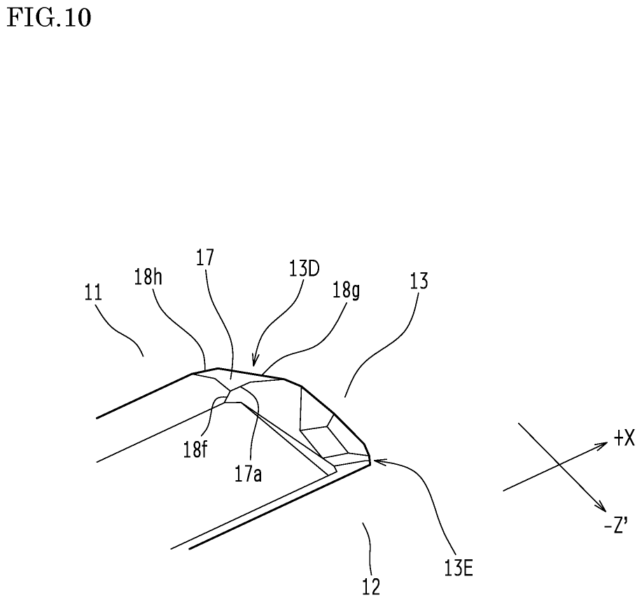

In the above-described embodiment, the shape of the intersection blocking part may be other than the C face 16. For example, an R face (rounded chamfered face) or a projection part may be used. Also, the intersection blocking part may have a shape combining the C face with the R face. In order to reliably prevent generation of break, it is preferable that the intersection blocking part has a shape of the R face (rounded chamfered shape). The intersection blocking part having the above shape can be easily formed by arranging the shape of the photomask when processing the crystal resonator plate 10 by wet etching. Furthermore, the intersection blocking part may be a new crystal face 17 by wet etching, as shown in FIG. 10. In the example shown in FIG. 10, a ridge line 18f that extends from the side of the connecting part 13A of the vibrating part 11 and the support part 13 on the first main surface side is connected to (intersects) an outer peripheral edge 17a of the new crystal face 17. Thus, the new crystal face 17 prevents the ridge line 18f from intersecting ridge lines 18g and 18h formed on the connecting part 13D of the vibrating part 11 and the support part 13 on the second main surface side. In this way, it is possible to eliminate concentration of stress in one point on the connecting part 13D of the vibrating part 11 and the support part 13 on the first main surface side, and also to prevent generation of cracks that originate from the stress concentration point. Thus, it is possible to prevent the connecting part of the vibrating part 11 and the support part 13 from being broken.

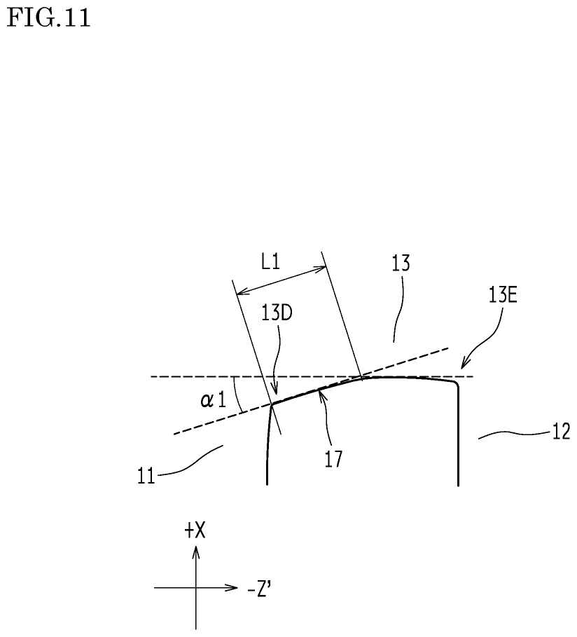

Here, as shown in FIG. 11, it is preferable that an inclination angle α1 of an inclined part of the new crystal face 17 as the intersection blocking part in plan view (bottom view) is 30° to 60°, and in particular, 45° is preferable. The inclination angle α1 is an angle of the direction in which the inclined part of the new crystal face 17 in plan view extends relative to the direction in which the support part 13 extends (here, in the Z′ axis direction). Also, it is preferable that a slope length L1 of the inclined part of the new crystal face 17 in plan view (bottom view) is 30 μm or more. For example, in the crystal resonator plate 10 having the size of 1.0×0.8 mm, the slope length L1 is preferably 30 to 50 μm when the thickness of the support part 13 is 20 to 40 μm and the length of the support part 13 is 60 to 200 μm. In particular, the above slope length L1 is preferable when the crystal resonator plate 10 is adaptable to the frequency at, for example, 40 to 60 MHz.

In the above-described embodiment, the plurality of ridge lines 18c, 18d and 18e may intersect only the outer peripheral edge 16a of the C face 16 on the connecting part 13D of the vibrating part 11 and the support part 13 on the second main surface side.

In the above-described embodiment, the crystal resonator plate 10 has only one support part (connecting part) 13 to connect the vibrating part 11 to the external frame part 12. However, two or more support parts 13 may be provided. In this case, the above-described embodiment may be applied to each connecting part connecting the support part 13 to the vibrating part 11.

In the above-described embodiment, the C face 16 as the intersection blocking part is provided on the connecting part 13D of the vibrating part 11 and the support part 13 on the second main surface side. However, the C face may be provided on the connecting part of the external frame part 12 and the support part 13, or also may be provided on both the connecting part of the vibrating part 11 and the support part 13 and the connecting part of the external frame part 12 and the support part 13. By providing the intersection blocking part on the connecting part of the external frame part 12 and the support part 13, this intersection blocking part prevents the concentration of a plurality of ridge lines formed by the plurality of crystal faces in one point on the connecting part of the external frame part 12 and the support part 13. In this way, it is possible to eliminate concentration of stress in one point on the connecting part of the external frame part 12 and the support part 13, and also to prevent generation of cracks that originate from the stress concentration point. Thus, it is possible to prevent the connecting part of the external frame part 12 and the support part 13 from being broken.

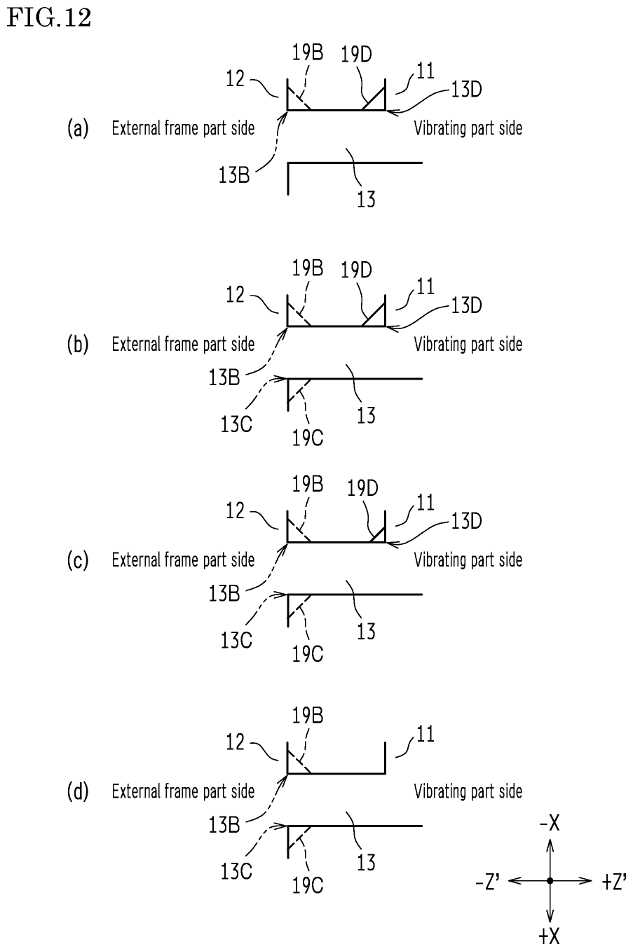

Here, a description is given on the case where a plurality of intersection blocking parts is provided referring to FIGS. 12. In the examples shown in FIGS. 12, two or three new crystal faces 19 (19B, 19C and 19D in FIGS. 12) are provided as the intersection blocking parts. The new crystal faces 19 may be, for example, the C face, the R face, or a face made by combining the C face with the R face. For convenience sake, in FIGS. 12, the new crystal faces 19 provided on the support part 13 on the second main surface side (on the side of the −Y direction) are shown as solid lines while the new crystal surfaces 19 provided on the support part 13 on the first main surface side (on the side of the +Y direction) are shown as broken lines.

In the crystal resonator plate 10 having a configuration as shown in FIGS. 4 and 5, at most six new crystal faces 19 can be formed. Specifically, the new crystal faces 19 can be respectively formed on: the connecting part 13A of the vibrating part 11 and the support part 13 on the first main surface side (see FIG. 4); the connecting part 13D of the vibrating part 11 and the support part 13 on the second main surface side (see FIG. 5); a connecting part 13B of the external frame part 12 and the support part 13 on the first main surface side in the −X direction (a first connecting part, see FIG. 4); a connecting part 13E of the external frame part 12 and the support part 13 on the second main surface side in the −X direction (a first connecting part, see FIG. 5); a connecting part 13C of the external frame part 12 and the support part 13 on the first main surface side in the +X direction (a second connecting part, see FIG. 4); and a connecting part 13F of the external frame part 12 and the support part 13 on the second main surface side in the +X direction (a second connecting part, see FIG. 5).

The number of the new crystal faces 19 that can be formed is different depending on the number and/or location of the support parts 13. For example, in the case where the support part 13 is not connected to the corner part of the vibrating part 11 but connected to a middle part of the vibrating part 11 in the X axis direction or in the Z′ axis direction, it is possible to form, at most, eight new crystal faces 19.

In the example shown in FIG. 12(a), the new crystal face 19D is formed on the connecting part 13D of the vibrating part 11 and the support part 13 on the second main surface side, and the new crystal face 19B is formed on the connecting part 13B of the external frame part 12 and the support part 13 on the first main surface side in the −X direction. The two new crystal faces 19B and 19D have the same inclination angle α1 (for example, 45°), and also have the same slope length L1 (for example, 30 μm).

In the examples shown in FIGS. 12(b) and 12(c), the new crystal face 19D is formed on the connecting part 13D of the vibrating part 11 and the support part 13 on the second main surface side, the new crystal face 19B is formed on the connecting part 13B of the external frame part 12 and the support part 13 on the first main surface side in the −X direction, and the new crystal face 19C is formed on the connecting part 13C of the external frame part 12 and the support part 13 on the first main surface side in the +X direction. In the example shown in FIG. 12(b), the three new crystal faces 19B, 19C and 19D have the same inclination angle α1 (for example, 45°), and also have the same slope length L1 (for example, 30 μm). On the other hand, in the example shown in FIG. 12(c), the three new crystal faces 19B, 19C and 19D have the same inclination angle α1 (for example, 45°), however, the one new crystal face 19D has the slope length L1 (for example, 25 μm) smaller than the slope length L1 (for example, 30 μm) of the two new crystal faces 19B and 19C.

In the example shown in FIG. 12(d), the new crystal face 19B is formed on the connecting part 13B of the external frame part 12 and the support part 13 on the first main surface side in the −X direction, and the new crystal face 19C is formed on the connecting part 13C of the external frame part 12 and the support part 13 on the first main surface side in the +X direction. The two new crystal faces 19B and 19C have the same inclination angle α1 (for example, 45°), and also have the same slope length L1 (for example, 30 μm).

The shear strength of each example (examples of FIGS. 12(a) to 12(d)) was measured, and the following was realized: it is preferable that the new crystal faces 19 are formed on both the vibrating part 11 side and the external frame part 12 side (for example, FIGS. 12(a) to 12(c)) compared to the case where the new crystal faces 19 are formed on only the external frame part 12 side (for example, FIG. 12(d)). In this way, by providing the new crystal faces 19 respectively on both sides of the support part 13 in the longitudinal direction, it is possible to disperse the stress, which prevents the connecting part from being broken.

It is also preferable that the new crystal faces 19 are formed on both the first main surface side (on the side of the +Y direction) and the second main surface side (on the side of the −Y direction) of the support part 13 (for example, FIGS. 12(a) to 12(c)) compared to the case where the new crystal faces 19 are formed on only the second main surface side (on the side of the −Y direction) of the support part 13 (for example, FIG. 12(d)). In this way, by providing the new crystal faces 19 respectively on both the first main surface side and the second main surface side of the support part 13, it is possible to disperse the stress, which prevents the connecting part from being broken.

It is also preferable that the new crystal faces 19 are formed on both the side of the +X direction and the side of the −X direction of the support part 13 (for example, FIG. 12(b)) compared to the case where the new crystal faces 19 are formed on only the side of the −X direction of the support part 13 (for example, FIG. 12(a)). In this way, by providing the new crystal faces 19 respectively on both the side of the −X direction and the side of the +X direction of the support part 13, it is possible to disperse the stress, which prevents the connecting part from being broken.

Also, it is preferable that the new crystal faces 19 are formed to have the same slope length L1 (for example, FIG. 12(b)) compared to the case where some of the new crystal faces 19 have different slope lengths L1 (for example, FIG. 12(c)).

In the above-described embodiment, the thickness of the vibrating part 11 and the support part 13 of the crystal resonator plate 10 may be thinner than the thickness of the external frame part 12.

In the above-described embodiment, the first sealing member 20 and the second sealing member 30 are each made of a crystal plate. However, the present invention is not limited thereto. The first sealing member 20 and the second sealing member 30 may be made of, for example, glass. Also, the material of the first sealing member 20 and the second sealing member 30 is not limited to the brittle material such as crystal and glass. A resin plate and a resin film may also be used as the material. In this case, the vibrating part 11 may be sealed by the resin plate or the resin film coated on the crystal resonator plate 10.

In the above-described embodiment, the crystal resonator having the sandwich structure is used as the crystal resonator 100, in which the crystal resonator plate is sandwiched between the first sealing member 20 and the second sealing member 30. However, the crystal resonator 100 having another structure may be used. For example, it is possible to use a crystal resonator having a structure including a base with a recess, which is made of an insulation material such as ceramic, glass and crystal. This base houses the crystal resonator plate 10 therein, and is sealed by a lid.

In the above-described embodiment, the number of the external electrode terminals 32 on the second main surface 302 of the second sealing member 30 is four. However, the present invention is not limited thereto. The number of the external electrode terminals 32 may be, for example, two, six, or eight. Also in the above-described embodiment, the present invention is applied to the crystal resonator 100. However, the present invention may also be applied to, for example, a crystal oscillator or the like.

This application claims priority based on Patent Application No. 2021-105678 filed in Japan on Jun. 25, 2021. The entire contents thereof are hereby incorporated in this application by reference.

### DESCRIPTION OF THE REFERENCE NUMERALS

10 Crystal resonator plate (piezoelectric resonator plate)
11 Vibrating part
12 External frame part
13 Support part
13A, 13D Connecting part
13B, 13C, 13E, 13F Connecting part (first/second connecting part)
16 C face (intersection blocking part)
17, 19B, 19C, 19D New crystal face (intersection blocking part)
18a-18h Ridge line
100 Crystal resonator (piezoelectric resonator device)

1. A piezoelectric resonator plate comprising: a vibrating part; an external frame part surrounding an outer periphery of the vibrating part; and a support part connecting the vibrating part to the external frame part, wherein
a plurality of crystal faces is formed on a side surface of the external frame part and on a side surface of the support part, both the side surfaces are connected to a first connecting part of the external frame part and the support part, and a plurality of ridge lines is formed by the plurality of crystal faces, and
a first intersection blocking part is provided on the first connecting part, on at least one side of a first main surface side and a second main surface side thereof, so as to block intersection of two or more of the plurality of ridge lines on the first connecting part.

2. The piezoelectric resonator plate according to claim 1, wherein
a plurality of crystal faces is formed on a side surface of the vibrating part and on the side surface of the support part, both the side surfaces are connected to a connecting part of the vibrating part and the support part, and a plurality of ridge lines is formed by the plurality of crystal faces, and
a second intersection blocking part is provided on the connecting part of the vibrating part and the support part, on at least one side of the first main surface side and the second main surface side thereof, so as to block intersection of two or more of the plurality of ridge lines on the connecting part.

3. The piezoelectric resonator plate according to claim 2, wherein
the first intersection blocking part is provided on one side of the first main surface side and the second main surface side, and
the second intersection blocking part is provided on the other side of the first main surface side and the second main surface side.

4. The piezoelectric resonator plate according to claim 1, wherein
a third intersection blocking part is provided on a second connecting part of the external frame part and the support part.

5. The piezoelectric resonator plate according to claim 2, wherein
a third intersection blocking part is provided on a second connecting part of the external frame part and the support part.

6. A piezoelectric resonator plate comprising: a vibrating part; an external frame part surrounding an outer periphery of the vibrating part; and a support part connecting the vibrating part to the external frame part, wherein
a plurality of crystal faces is formed on a side surface of the vibrating part and on a side surface of the support part, both the side surfaces are connected to a connecting part of the vibrating part and the support part, and a plurality of ridge lines is formed by the plurality of crystal faces, and
a second intersection blocking part is provided on the connecting part of the vibrating part and the support part, on at least one side of a first main surface side and a second main surface side thereof, so as to block intersection of two or more of the plurality of ridge lines on the connecting part.

7. The piezoelectric resonator plate according to claim 1, wherein
each intersection blocking part is a new crystal face or a projection part.

8. The piezoelectric resonator plate according to claim 1, wherein
the piezoelectric resonator plate is an AT-cut crystal plate,
the first main surface and the second main surface are provided to be parallel to an XZ′ plane of the AT-cut crystal plate,
the piezoelectric resonator plate has only one support part, and the support part extends from a corner part positioned in a +X direction and in a −Z′ direction of the vibrating part toward the −Z′ direction, and
the side surface of the support part is a side surface on a side of a −X direction of the support part, and the side surface of the external frame part is connected to the side surface of the support part.

9. A piezoelectric resonator device comprising the piezoelectric resonator plate according to claim 1.

10. The piezoelectric resonator plate according to claim 6, wherein
each intersection blocking part is a new crystal face or a projection part.

11. The piezoelectric resonator plate according to claim 6, wherein
the piezoelectric resonator plate is an AT-cut crystal plate,
the first main surface and the second main surface are provided to be parallel to an XZ′ plane of the AT-cut crystal plate,
the piezoelectric resonator plate has only one support part, and the support part extends from a corner part positioned in a +X direction and in a −Z′ direction of the vibrating part toward the −Z′ direction, and
the side surface of the support part is a side surface on a side of a −X direction of the support part, and the side surface of the external frame part is connected to the side surface of the support part.

12. A piezoelectric resonator device comprising the piezoelectric resonator plate according to claim 6.
